(19) United States
(12) Patent Application Publication
(10) Pub. No.: US 2025/0218916 A1
(43) Pub. Date: Jul. 3, 2025

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventors: Seungwan Shin, Suwon-si (KR); Junghyun Lee, Suwon-si (KR)

(21) Appl. No.: 18/732,066

(22) Filed: Jun. 3, 2024

(30) Foreign Application Priority Data
Dec. 28, 2023 (KR) 10-2023-0193881

(51) Int. Cl. H01L 23/498; H01L 21/311; H01L 23/00; H01L 25/10

(52) U.S. Cl. CPC H01L 23/49838; H01L 21/31111; H01L 21/31144; H01L 23/49822; H01L 23/49866; H01L 24/08; H01L 24/48; H01L 25/105; H01L 2224/08225; H01L 2224/48145; H01L 2224/48225; H01L 2225/1058; H01L 2924/1815

(57) ABSTRACT

A semiconductor package includes a first insulating layer, a second insulating layer on the first insulating layer, the second insulating layer having an opening, a pad on the first insulating layer or the second insulating layer to at least partially vertically overlap the opening, and a pad surface layer on an upper surface of the pad to at least partially vertically overlap the opening, the pad surface layer including a conductive material different from that of the pad. The upper surface of the pad is recessed to have a shape more curved than that of a lower surface of the pad.

### CROSS-REFERENCE TO RELATED APPLICATION(S)

This application claims benefit of priority to Korean Patent Application No. 10-2023-0193881, filed on Dec. 28, 2023 in the Korean Intellectual Property Office, the disclosure of which is incorporated herein by reference in its entirety.

### BACKGROUND

The present inventive concept relates to a semiconductor package and a method of manufacturing the semiconductor package.

In general, a semiconductor chip may be implemented as a semiconductor package such as a wafer level package (WLP) or a panel level package (PLP), and the semiconductor package may be used as an electronic component of a device.

The semiconductor package may include a redistribution layer for electrically connecting a semiconductor chip to a device or a printed circuit board. The redistribution layer may have a structure in which a redistribution line, implemented to be finer than an interconnection line of an interconnection layer of a general printed circuit board, extends horizontally.

The redistribution layer may be electrically connected to a bump to vertically extend an electrical connection path. A pad may be disposed to overlap an opening of an insulating layer, and may be electrically connected to the bump disposed in the opening. The pad may also be implemented with under bump metallurgy (UBM).

### SUMMARY

The present inventive concept provides a semiconductor package and a method of manufacturing a semiconductor package in which a combination structure of a pad and an insulating layer has efficiently improved reliability (for example, performance to prevent at least one of voids, cracks, and delamination).

According to an aspect of the present inventive concept, there is provided a semiconductor package including a first insulating layer, a second insulating layer on the first insulating layer, the second insulating layer having an opening, a pad on the first insulating layer or the second insulating layer to at least partially vertically overlap the opening, and a pad surface layer on an upper surface of the pad to at least partially vertically overlap the opening, the pad surface layer including a conductive material different from that of the pad. The upper surface of the pad may be recessed to have a shape more curved than that of a lower surface of the pad.

According to another aspect of the present inventive concept, there is provided a semiconductor package including a first insulating layer, a second insulating layer on the first insulating layer, the second insulating layer having an opening, a pad on the first insulating layer or the second insulating layer to at least partially vertically overlap the opening, and a pad surface layer on an upper surface of the pad to at least partially vertically overlap the opening, the pad surface layer including a conductive material different from that of the pad. An edge of a lower surface of the pad surface layer may be at a higher vertical level than a center of an upper surface of the pad surface layer.

According to another aspect of the present inventive concept, there is provided a method of manufacturing a semiconductor package including forming a pad on a seed layer on a first insulating layer, and forming a mask layer on an edge region of the pad and the seed layer, etching a portion of a central region of the pad, plating the central region of the pad, removing the mask layer, and etching a portion of the seed layer not vertically overlapping the pad.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view illustrating a semiconductor package according to example embodiments of the present inventive concept;

FIG. 1B is a plan view illustrating a semiconductor package according to example embodiments of the present inventive concept;

FIG. 2 is a cross-sectional view illustrating a structure in which a semiconductor package includes an additional semiconductor package according to example embodiments of the present inventive concept;

FIGS. 3A and 3B are enlarged cross-sectional views of a bump connection portion of a semiconductor package according to example embodiments of the present inventive concept;

FIGS. 4A to 4E are cross-sectional views illustrating a semiconductor package manufacturing method according to example embodiments of the present inventive concept;

FIGS. 5A to 5C are enlarged cross-sectional views of a bump connection portion of a semiconductor package according to example embodiments of the present inventive concept;

FIG. 6A is a cross-sectional view illustrating a structure in which a bump connection portion of a semiconductor package is implemented as a lower side of the semiconductor package according to example embodiments of the present inventive concept;

FIG. 6B is a cross-sectional view illustrating a structure in which a semiconductor package includes additional semiconductor chips according to example embodiments of the present inventive concept; and

FIGS. 7A and 7B are cross-sectional views illustrating various structures of a vertical connection member of a semiconductor package according to example embodiments of the present inventive concept.

### DETAILED DESCRIPTION

The detailed description of the present inventive concept to be described below refers to the accompanying drawings which, by way of example, illustrate embodiments in which the present inventive concept may be practiced. These embodiments are described in sufficient detail to enable one skilled in the art to practice the present inventive concept. It should be understood that the various embodiments of the present inventive concept are different from each other but are not necessarily mutually exclusive.

For example, an example embodiment of specific shapes, structures, and characteristics described herein may be implemented in another embodiment without departing from the spirit and scope of the present inventive concept. Additionally, it should be understood that the location or arrangement of individual components within each disclosed embodiment may be changed without departing from the spirit and scope of the present inventive concept. Accordingly, the detailed description set forth below is not intended to be taken in a limiting sense, and the scope of the present inventive concept is limited only by the appended claims, with all equivalents as claimed by those claims. Like reference numbers in the drawings indicate the same or similar features or function throughout the various aspects.

Hereinafter, example embodiments of the present inventive concept will be described in detail with reference to the accompanying drawings such that those skilled in the art may easily practice the present inventive concept.

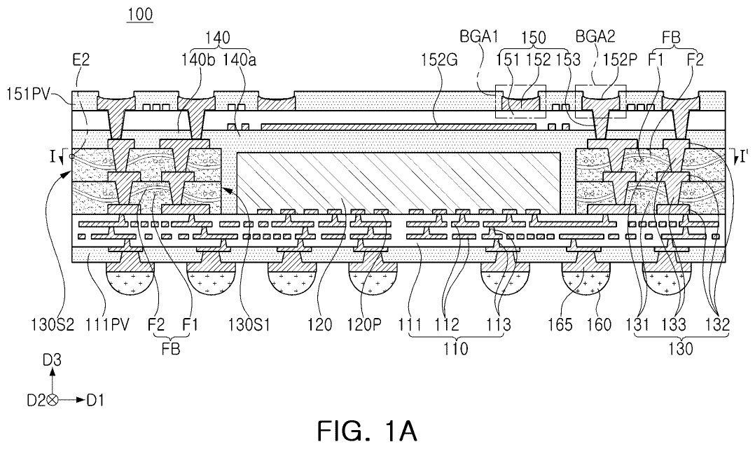

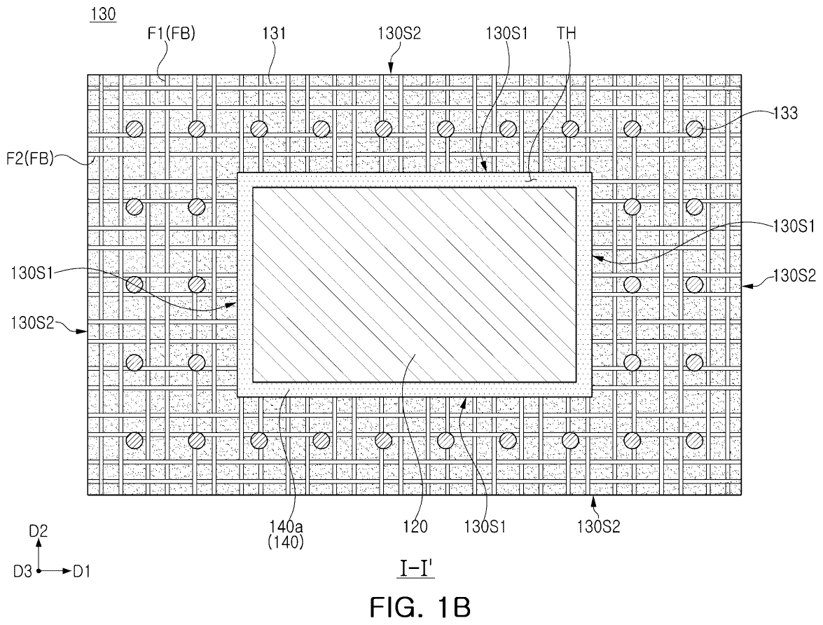

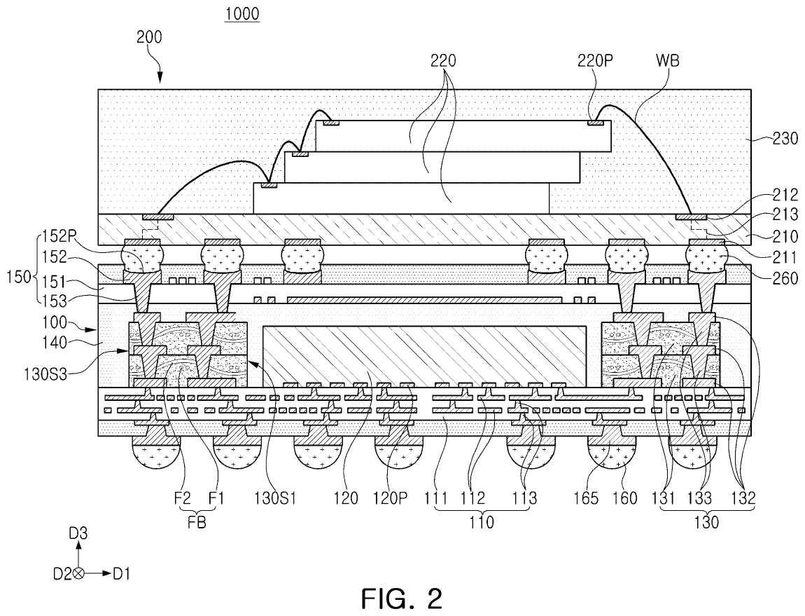

FIG. 1A illustrates a cross-section of a semiconductor package 100 according to example embodiments of the present inventive concept, taken along a plane formed by a first direction D1 and a third direction D3. FIG. 1B illustrates a cross-section of the semiconductor package 100 of FIG. 1A, taken from I to I′ along a plane formed by the first direction D1 and a second direction D2. FIG. 2 illustrates a cross-section of the semiconductor package 1000 according to example embodiments of the present inventive concept, having a structure in which an additional semiconductor package 200 is connected to the semiconductor package 100 of FIG. 1A.

Referring to FIGS. 1A, 1B, and 2, the semiconductor package 100 according to example embodiments of the present inventive concept may include at least one of a redistribution structure 110, a semiconductor chip 120, a vertical connection member 130, a encapsulant 140, and a bump connection portion 150.

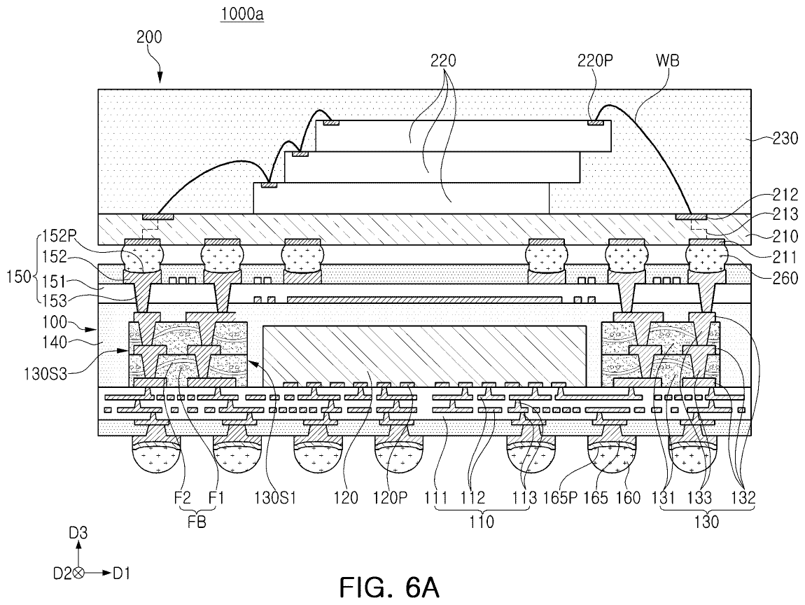

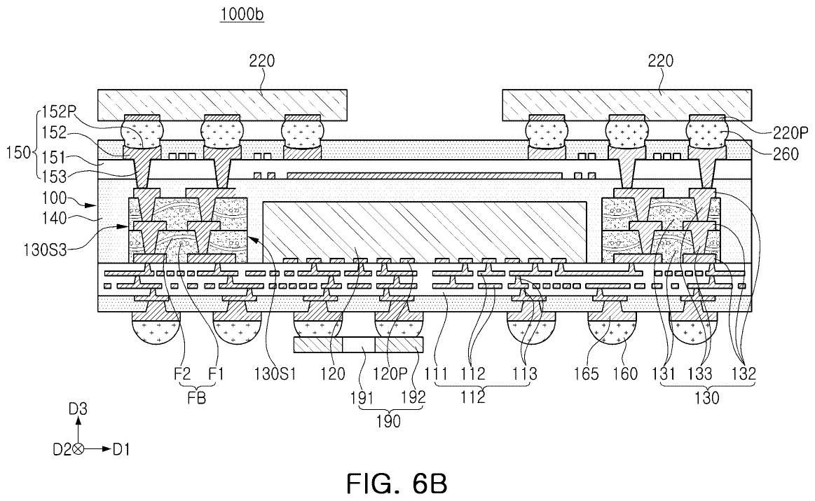

The semiconductor package 100 may be at least a portion of a system in package (SIP) or a portion of a package on package (POP) structure. For example, the semiconductor package 100 may be electrically connected to an additional semiconductor package 200 or an additional semiconductor chip (220 in FIG. 6B) on an upper side thereof through a pad 152 and a bump, thereby forming a POP structure.

The redistribution structure 110 may have a structure in which at least one redistribution layer 112 and at least one first insulating layer 111 are alternately stacked. The redistribution structure 110 may further include redistribution vias 113 extending from at least one redistribution layer 112 in a stacking direction (for example, a third direction D3) of the redistribution structure 110. The redistribution vias 113 may pass through the at least one first insulating layer 111.

The at least one first insulating layer 111 may include an insulating material, and may include, for example, a thermosetting resin such as an epoxy resin or a thermoplastic resin such as polyimide. For example, the at least one first insulating layer 111 may include a photosensitive insulating material such as a photoimageable dielectric (PID) resin. Alternatively, the at least one insulating layer 111 may include a resin mixed with an inorganic filler, for example, an Ajinomoto Build-up Film (ABF). Alternatively, the at least one first insulating layer 111 may include prepreg, flame retardant (FR-4), or bismaleimide triazine (BT). The at least one first insulating layer 111 may include the same material or different materials. Depending on a material, a process, and the like of respective layers, a boundary therebetween may not be distinguished.

The redistribution layers 112 and the redistribution vias 113 may form electrical paths. The redistribution layers 112 may be disposed on the plane formed by the first direction D1 and the third direction D3 to have a linear shape, and the redistribution vias 113 may have a cylindrical shape having side surfaces that are inclined such that a width thereof becomes narrower toward a lower portion thereof or an upper portion thereof. The redistribution vias 113 are illustrated as a filled via structure completely filled with a conductive material, but the present disclosure is not limited thereto. For example, the redistribution vias 113 may have a conformal via shape in which a metal material is formed along an inner wall of a via hole. The redistribution layers 112 and the redistribution vias 113 may include a conductive material, for example, copper (Cu), aluminum (Al), silver (Ag), tin (Sn), gold (Au), nickel (Ni), lead (Pb), titanium (Ti), or alloys thereof.

The redistribution structure 110 may be electrically connected to the bump connection portion 150. For example, the redistribution structure 110 may be electrically connected to the pad 152 of the bump connection portion 150 through the electrical paths of the redistribution structure 110 and the vertical connection member 130.

The semiconductor chip 120 may be electrically connected to the redistribution structure 110, and may be disposed between the redistribution structure 110 and a first insulating layer 151. For example, the semiconductor chip 120 may include a body portion and connection pads 120P, and may be electrically connected to the electrical paths of the redistribution structure 110 through the connection pads 120P.

For example, the connection pads 120P may include a conductive material such as tungsten (W), aluminum (Al), copper (Cu), or the like, and may be a pad of a bare chip, for example, an aluminum (Al) pad. However, in some example embodiments, the connections pads 120P may be a pad of a packaged chip, for example, a copper (Cu) pad. For example, the body portion may contain or include a semiconductor material such as silicon (Si), germanium (Ge), gallium arsenide (GaAs), or the like, and a portion of the body portion may be a device layer including an integrated circuit (IC).

An electrical connection method between the connection pads 120P and the redistribution structure 110 is not particularly limited. For example, the semiconductor chip 120 may be mounted on the redistribution structure 110 through a lower surface thereof using a flip-chip bonding method, and may also be electrically connected to the redistribution structure 110 through an upper surface of the semiconductor chip 250 using a wire bonding method. In the flip-chip bonding method, whether to use a bump may be selective.

The semiconductor chip 120 may include a logic semiconductor chip and/or a memory semiconductor chip. The logic semiconductor chip may be a microprocessor, for example, a central processing unit (CPU), a graphic processing unit (GPU), a field programmable gate array (FPGA), an application processor (AP), a digital signal processor, a cryptographic processor, a controller, or an application specific integrated circuit (ASIC). The memory semiconductor chip may be a volatile memory such as dynamic random access memory (DRAM), static random access memory (SRAM), or the like, or a non-volatile memory such as flash memory or the like.

The number of semiconductor chips 120 is not limited to one. For example, the semiconductor chip 120 may have a structure in which semiconductor chips are stacked in the third direction D3, and an electrical connection method between the semiconductor chips may be similar to an electrical connection method between the semiconductor chip 120 and the redistribution structure 110, or may be a direct bonding method or a hybrid bonding method.

The vertical connection member 130 may surround the semiconductor chip 120, and may be disposed between the redistribution structure 110 and the first insulating layer 151. An internal surface 130S1 of the vertical connection member 130 may oppose or face the semiconductor chip 120, and an external surface 130S2 of the vertical connection member 130 may be portion of a cut surface of the semiconductor package 100 (and may face away from the semiconductor chip 120). The vertical connection member 130 may include at least one of a connection member insulating layer 131, a connection member conductive layer 132, and a connection member via 133.

For example, the connection member insulating layer 131 may contain or include at least some of insulating materials that may be contained or included in the redistribution insulating layers 111, or may contain or include an insulating material (for example, a core of a printed circuit board, an insulating layer of a CCL, or the like) having rigidity stronger than those of the redistribution insulating layers 111. For example, a thickness of one connection member insulating layer 131 may be greater than a thickness of the redistribution insulating layers 111, and may be greater than a thickness of the first insulating layer 151. For example, the connection member insulating layer 131 may have a structure in which a fiber layer FB including first and second fibers F1 and F2 is mixed with an insulating material. For example, an end E2 of the fibrous layer FB may be exposed to or correspond to the external surface 130S2 of the vertical connection member 130, but the present inventive concept is not limited thereto.

The connection member conductive layer 132 may be disposed on an upper surface and/or a lower surface of the connection member insulating layer 131, and the connection member via 133 may pass through the connection member insulating layer 131. The connection member conductive layer 132 and the connection member via 133 may be implemented in a similar manner (dimensions may be different) as the redistribution layers 112 and the redistribution vias 113, but the present inventive concept is not limited thereto.

The encapsulant 140 may encapsulate the semiconductor chip 120, between the redistribution structure 110 and the first insulating layer 151. The encapsulant 140 may fill or be in an empty space between the redistribution structure 110 and the first insulating layer 151, thereby improving robustness of the semiconductor chip 120 against the outside, and also improving durability (for example, robustness against external impact) or reliability (internal warpage prevention performance) of the semiconductor package 100. A portion 140a of the encapsulant 140 may be surrounded by the vertical connection member 130, and another portion 140b of the encapsulant 140 may form a layer, between he vertical connection member 130 and the first insulating layer 151. The other portion 140b of the encapsulant 140 may surround a portion of the conductive via 153, and the conductive via 153 may pass through the other portion 140b of the encapsulant 140.

For example, the encapsulant 140 may contain or include a molding material such as an epoxy molding compound (EMC). However, a material that may be contained or included in the encapsulant 140 is not limited to the molding material, and may contain or include an insulating material having protection properties similar to those of the molding material or having high ductility. For example, the insulating material may be a build-up film (for example, an Ajinomoto build-up film (ABF)), or may be a thermosetting resin such as an epoxy resin or a thermoplastic resin such as polyimide.

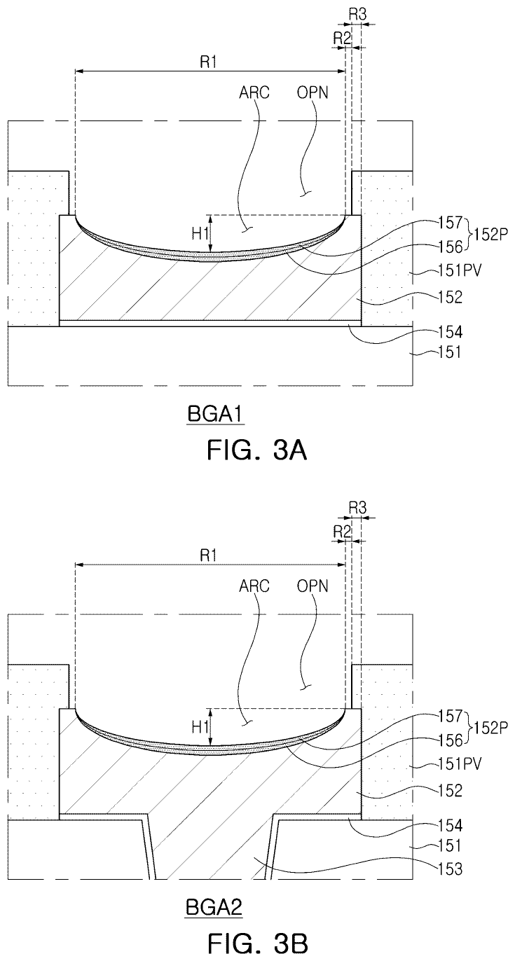

FIG. 3A illustrates an enlarged view of a first bump connection portion BGA1 of the bump connection portion 150 of FIG. 1A. FIG. 3B illustrates an enlarged view of A second bump connection portion BGA2 of the bump connection portion 150 of FIG. 1A. In the present inventive concept, a structure of a semiconductor package in which the first and second bump connection portions BGA1 and BGA2 are disposed is not limited to FIGS. 1A to 2. For example, the semiconductor package according to the present inventive concept may not include at least one of the redistribution structure 110, the semiconductor chip 120, the vertical connection member 130, and the encapsulant 140 of FIG. 1A.

Referring to FIGS. 1A, 3A, and 3B, the bump connection portions 150, BGA1, and BGA2 of the semiconductor package 100 according to example embodiments of the present inventive concept may include a first insulating layer 151 and a second insulating layer 151PV, a pad 152, and a pad surface layer 152P. The bump connection portions 150, BGA1, and BGA2 may be represented as UBM.

The second insulating layer 151PV may be disposed on the first insulating layer 151, and may have an opening OPN. The first and second insulating layers 151 and 151PV may contain or include at least some of the insulating materials that may be included in the redistribution insulating layers 111. For example, the first and second insulating layers 151 and 151PV may contain or include a build-up film that is effective in forming the opening OPN, and may contain or include a material that may be contained or included in a solder resist layer of a printed circuit board. For example, the build-up film may be an ABF. For example, the opening OPN may be formed using a photolithography method, and a shape of the opening OPN may be close to a cylindrical shape having an upper surface and a lower surface having different sizes. Depending on the design, the first and second insulating layers 151 and 151PV may contain or include different insulating materials. For example, the first insulating layer 151 may contain or include prepreg, and the second insulating layer 151PV may contain or include ABF.

The first insulating layer 151 may provide an arrangement space for redistribution lines 152G, and the redistribution lines 152G may have a shape extending on the plane formed by the first and second directions D1 and D2, and may be electrically connected to the vertical connection member 130.

The pad 152 may be disposed on the first insulating layer 151 or the second insulating layer 151PV to overlap the opening OPN. For example, the pad 152 may be disposed on an upper surface of the first insulating layer 151, and may be disposed on a side surface of the second insulating layer 151PV. For example, the pad 152 may have a circular or polygonal plate shape, and may contain or include at least some of the materials that may be contained or included in the redistribution layer 112.

The bump connection portions 150, BGA1, and BGA2 may further include a seed layer 154 disposed between the first insulating layer 151 and the pad 152. The seed layer 154 may assist in forming the pad 152. For example, the seed layer 154 may be formed by performing sputtering, and the pad 152 may be formed by performing electroless plating on the seed layer 154. The seed layer 154 may contain or include a material (for example, Ti or TiW), different from those of the pad 152 and the pad surface layer 152P.

The pad 152 of the second bump connection portion BGA2 of FIG. 3B may have a conductive via 153 extending downwardly from a lower surface of the pad 152, the conductive via 153 vertically overlapping the pad surface layer 152P. The first bump connection portion BGA1 of FIG. 3A may not include the conductive via 153, and may be electrically connected to the redistribution lines 152G. When the pad 152 has a conductive via 153, a portion of the seed layer 154 may be disposed on a side surface of the conductive via 153. For example, a combination structure of the conductive via 153 and the pad 152 may be formed by performing a semi-additive process (SAP) or a modified semi-additive process (MSAP).

The pad surface layer 152P may be disposed on an upper surface of the pad 152 to overlap the opening OPN, and may contain or include a conductive material (for example, Ni, Au, AG, Pd, or alloys thereof), different from a material (for example, Cu or an alloy of copper) of the pad 152. For example, when viewed in the third direction D3, the pad surface layer 152P may have a circular or polygonal shape, and a width R1 of the pad surface layer 152P may be narrower than a width (R1+R2) of the opening OPN, and may be narrower than a width (R1+R2+R3) of the pad 152. The pad surface layer 152P may include at least one of the first and second pad surface layers 156 and 157 containing or including different conductive materials.

The pad 152 may have a conductive material (for example, Cu or an alloy of copper) having high conductivity for electrical connection efficiency, and the conductive material may have high wettability with respect to a material of a bump (for example, a solder material). The high conductivity and wettability of the pad 152 may cause a strong interaction (for example, bonding force or attractive force) between the pad 152 and the bump. The interaction may be represented as copper consumption when the conductive material is copper, and may affect arrangement reliability of the pad 152. The pad surface layer 152P may contain or include a conductive material (for example, Ni, Au, Ag, Pd, or alloys thereof), different from that of the pad 152, such that the effect of the interaction on the arrangement reliability of the pad 152 may be reduced.

For example, the first pad surface layer 156 may contain or include nickel (Ni) or an alloy of nickel, and may be disposed between the second pad surface layer 157 and the pad 152. Nickel may have a low chemical affinity for copper, and may have resistance to diffusion of copper, such that the effect of the interaction on the arrangement reliability of the pad 152 may be effectively reduced.

For example, the second pad surface layer 157 may contain or include gold (Au) or an alloy of gold, and may be disposed on an upper surface of the first pad surface layer 156. Due to gold (Au) having high conductivity, high malleability and high ductility, the opening OPN may be more densely filled even when the opening OPN is small. Accordingly, the second pad surface layer 157 may be advantageous for improving a degree of integration of the opening OPN.

In the semiconductor package 100, the number of bump connection portions 150, BGA1, and BGA2 may be plural in number, and a large number of bump connection portions 150, BGA1, and BGA2 may be present to correspond to the total number of paths electrically connected to the semiconductor package 100 and an additional semiconductor package (200 in FIG. 2) on an upper side thereof or an additional semiconductor chip (220 in FIG. 6B). Accordingly, a ratio (corresponding to a degree of integration of the opening OPN) of a total horizontal area of the opening OPN to a total horizontal area of the second insulating layer 151PV may not be low. As the additional semiconductor package (200 in FIG. 2) on the upper side thereof or the additional semiconductor chip (220 in FIG. 6B) has higher performance, the ratio may increase. As the ratio increases, a level of difficulty of securing reliability (for example, performance to prevent voids, cracks, and delamination) of the bump connection portions 150, BGA1, and BGA2 may also increase.

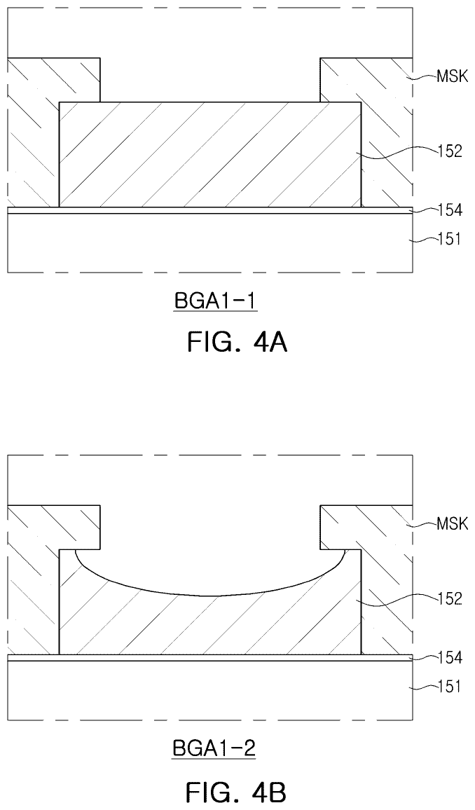

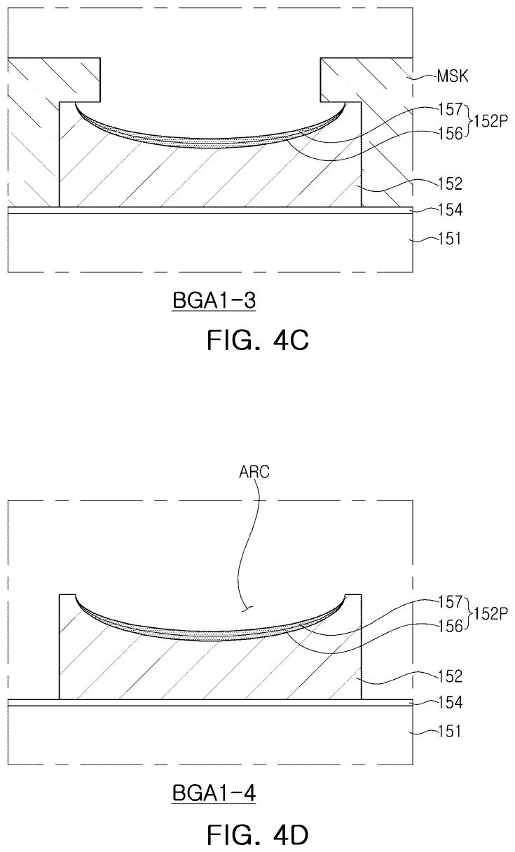

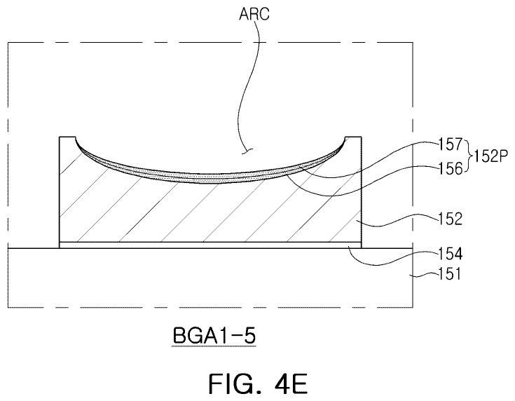

For example, the pad 152 may be separated from an edge of the pad surface layer 152P during a manufacturing process (for example, the manufacturing process of FIGS. 4D and 4E), and a space between the edge of the pad surface layer 152P and the pad 152 may be a space that may not be easily occupied by the second insulating layer 151PV. As the second insulating layer 151PV properly occupies the space, a combination structure of the pad 152 and the second insulating layer 151PV may have improved reliability. For example, as the space is longer, the second insulating layer 151PV may properly occupy the space. Alternatively, when the possibility of separation between the edge of the pad surface layer 152P and the pad 152 is reduced, the bump connection portions 150, BGA1, and BGA2 may have improved reliability.

The bump connection portions 150, BGA1, and BGA2 may have a recessed portion ARC in an upper side thereof. Depending on the recessed portion ARC, the upper surface of the pad 152 may be recessed to have a shape more curved than that of a lower surface of the pad 152 (which lower surface may be planar). Alternatively, depending on the recessed portion ARC, an edge of a lower surface of the pad surface layer 152P may be positioned to be higher than a center of an upper surface of the pad surface layer 152P.

Accordingly, the possibility of separation between the edge of the pad surface layer 152P and the pad 152 may be reduced, thereby improving reliability (for example, performance to prevent at least one of voids, cracks, and delamination) of the bump connection portions 150, BGA1, and BGA2. Even when the edge of the pad surface layer 152P and the pad 152 are separated from each other, a height of the space between the edge of the pad surface layer 152P and the pad 152 may be increased. Accordingly, the second insulating layer 151PV may properly occupy the space, and the bump connection portions 150, BGA1, and BGA2 may have improved reliability.

For example, a curved shape of the upper surface of the pad 152 may be implemented using an etching method involving a chemical reaction or a wet etching method, and a curved shape of the pad surface layer 152P may be implemented by performing electroless plating on the curved upper surface of the pad 152 at a substantially constant thickness. For example, the upper surface of the pad 152 may have a reversed arch shape, and the pad surface layer 152P may have a reversed arch shape. The upper surface of the pad 152 may be upwardly concave and the pad surface layer 152P may be upwardly concave.

The recessed portion ARC may be formed in the upper surface of the pad 152 to have a curved shape, such that a central region of the pad 152 may be thinner than an edge region of the pad 152. A depth Hl of the recessed portion ARC is not particularly limited, but may be greater than a thickness of the pad surface layer 152P, and may be less than a thickness of the central region of the pad 152. For example, thickness may be measured by performing analysis using at least one of a micrometer, a transmission electron microscopy (TEM), an atomic force microscope (AFM), a scanning electron microscope (SEM), a focused ion beam (FIB) optical microscope, and a surface profiler.

FIGS. 4A to 4E illustrate a method of manufacturing a semiconductor package according to example embodiments of the present inventive concept. The bump connection portions 150, BGA1, and BGA2 of the semiconductor package 100 of FIGS. 1A, 3A, and 3B may be manufactured by the semiconductor package manufacturing method illustrated in FIGS. 4A to 4E, but the present inventive concept is not limited thereto.

Referring to FIG. 4A, the semiconductor package manufacturing method according to example embodiments of the present inventive concept may include forming a pad 152 on a seed layer 154 on a first insulating layer 151, and forming a mask layer MSK on an edge region of the pad 152 and the seed layer 154 (BGA1-1). For example, the mask layer MSK may include dry film photoresist, may contain or include a material having chemical resistance, and may contain or include a material that is not substantially etched in an etching operation using a wet etching method or a dry etching method. For example, the mask layer MSK may be formed to entirely cover the pad 152, and a portion of the mask layer MSK, vertically overlapping the central region of the pad 152, may be removed using a photolithography method.

Referring to FIG. 4B, the semiconductor package manufacturing method according to example embodiments of the present inventive concept may include etching a portion of the central region of the pad 152 (BGA1-2). For example, the etching operation (BGA1-2) may use an etching method involving a chemical reaction or a wet etching method. The etching method involving a chemical reaction may include an etching gas or an etchant chemically reacting with an etching target (for example, a portion of the pad 152), and may include not only a chemical etching method but also a physicochemical etching method (for example, an RIE process).

Due to the nature of the etching method involving a chemical reaction or the wet etching method, a width of the removed portion of the mask layer MSK (the portion vertically overlapping the central region of the pad 152) may be narrower than a width of the etched portion of the pad 152, and an upper surface of the pad 152 may be more curved than a lower surface of the pad 152. The width of the etched portion of the pad 152 and a specific shape of the upper surface of the pad 152 may be adjusted by adjusting an etch rate. The adjustment of an etch rate may be implemented by adjusting temperature of etching gas or etchant, adjusting a spraying method, and adjusting process time.

Referring to FIG. 4C, the semiconductor package manufacturing method according to example embodiments of the present inventive concept may include plating the central region of the pad (BGA1-3). Accordingly, the pad surface layer 152P may be formed to have a shape corresponding to the shape of the upper surface of the pad 152. For example, the plating operation (BGA1-3) may be electroless plating.

Referring to FIG. 4D, the semiconductor package manufacturing method according to example embodiments of the present inventive concept may include removing the mask layer (BGA1-4). For example, the removing operation (BGA1-4) may be implemented by a strip process.

Referring to FIG. 4E, the semiconductor package manufacturing method according to example embodiments of the present inventive concept may include etching a portion of the seed layer 154 not vertically overlapping the pad 152 (BGA1-5). A portion of a side surface of the pad 152 may also be etched by performing the etching operation (BGA1-5). The etching operation (BGA1-5) may use one of the etching methods that may be used in the etching operation (BGA1-2). Accordingly, an etch rate between an upper portion and a lower portion of the side surface of the pad 152 may vary, but the present inventive concept is not limited thereto.

In the semiconductor package manufacturing method according to example embodiments of the present inventive concept, the etching operation (BGA1-5) may be performed after the etching operation (BGA1-2), thereby reducing the risk of a reliability degradation factor (for example, voids or cracks) occurring between the pad 152 and a second insulating layer (151PV in FIG. 1) to be formed below.

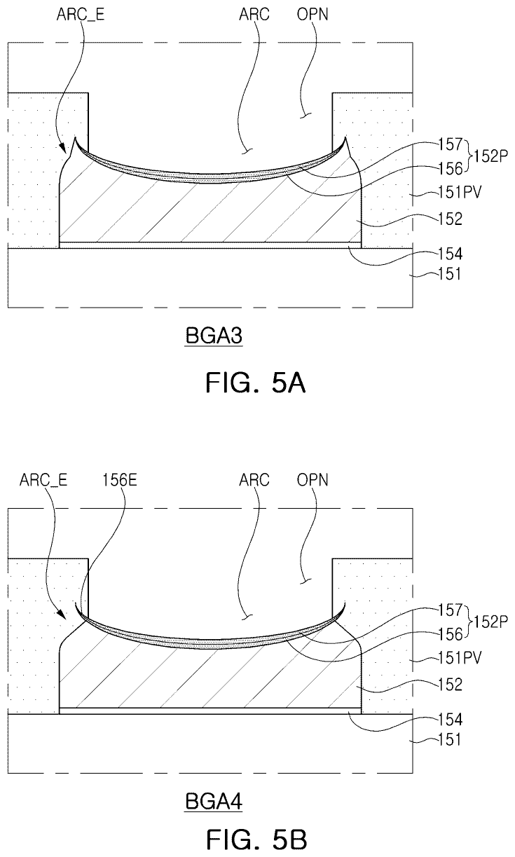

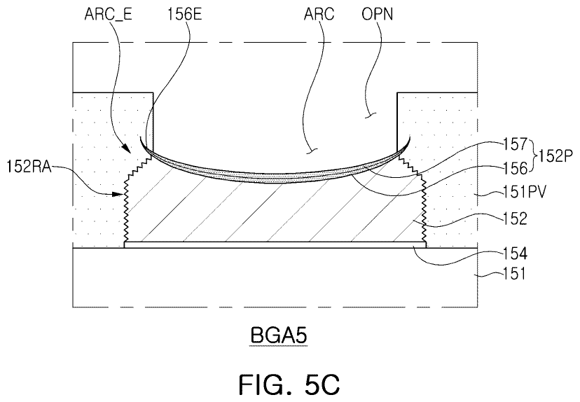

FIGS. 5A to 5C illustrate various modifications of the bump connection portions 150, BGA1, and BGA2 of the semiconductor package 100 of FIGS. 1A, 3A, and 3B.

Referring to FIGS. 5A to 5C, bump connection portions BGA3, BGA4, and BGA5 of a semiconductor package according to example embodiments of the present inventive concept may include an edge recessed portion ARC_E formed in an upper portion of a side surface of a pad 152. Depending on the edge recessed portion ARC_E, the upper portion of the side surface of the pad 152 may be more inclined than a lower portion of the side surface of the pad 152. For example, the edge recessed portion ARC_E may be formed by performing the etching operation (BGA1-5) illustrated in FIG. 4E.

When the edge recessed portion ARC_E is formed to be excessively deep, it may be difficult for a second insulating layer 151PV to occupy the edge recessed portion ARC_E, and improvement in reliability of the bump connection portions BGA3, BGA4, and BGA5 may be limited. However, the bump connection portions BGA3, BGA4, and BGA5 of the semiconductor package according to example embodiments of the present inventive concept may have a recessed portion ARC, and thus may have a structure in which the edge recessed portion ARC_E is not formed to be excessively deep, and the bump connection portions BGA3, BGA4, and BGA5 may have further improved reliability.

Referring to FIGS. 5B and 5C, the bump connection portions BGA4 and BGA5 of the semiconductor package according to example embodiments of the present inventive concept may have a structure in which a central region of a pad surface layer 152P is in contact with the pad 152 and an edge 156E of the pad surface layer 152P is spaced apart from the pad 152. For example, the structure may be formed by performing the etching operation (BGA1-5) illustrated in FIG. 4E.

When a space between the edge 156E of the pad surface layer 152P and the pad 152 has an excessively low height, it may be difficult for the second insulating layer 151PV to occupy the space between the edge 156E of the pad surface layer 152P and the pad 152, and improvement in reliability of the bump connection portions BGA4 and BGA5 may be limited. However, the bump connection portions BGA4 and BGA5 of the semiconductor package according to example embodiments of the present inventive concept may have a recessed portion ARC, such that the space may not have an excessively high height, and the bump connection portions BGA4 and BGA5 may have further improved reliability.

Referring to FIG. 5C, the pad 152 of the bump connection portion BGA5 of the semiconductor package according to example embodiments of the present inventive concept may have a roughness-treated side surface 152RA. Accordingly, adhesion between the pad 152 and the second insulating layer 151PV may be further improved.

FIG. 6A is a cross-sectional view illustrating a structure in which a bump connection portion of a semiconductor package 1000a is implemented as a lower side of the semiconductor package 1000a according to example embodiments of the present inventive concept.

Referring to FIG. 6A, the semiconductor package 1000a according to example embodiments of the present inventive concept includes additional pads 165 disposed on a lower surface of a redistribution structure 110, and additional pad surface layers 165P disposed on lower surfaces of the additional pads 165. The lower surface of the additional pad 165 may be recessed to have a shape more curved than that of an upper surface of the additional pad 165. Alternatively, an edge of an upper surface of the additional pad surface layer 165P may be positioned to be lower than an edge of a lower surface of the additional pad surface layer 165P. Accordingly, the additional pad 165 and a surrounding structure thereof may have improved reliability (for example, board level reliability (BLR)). A combination structure of the additional pad 165 and the additional pad surface layer 165P may be in direct contact with the additional bump 160.

That is, depending on the design, the additional pad 165 and the additional pad surface layer 165P may be implemented in substantially the same manner as the bump connection portion 150. Accordingly, the bump connection portions BGA1, BGA2, BGA3, BGA4, and BGA5 of FIGS. 3A to 5C may also be implemented in the additional pad 165 and the additional pad surface layer 165P, and a pad 152 may include the additional pad 165, and a pad surface layer 152P may include the additional pad surface layer 165P.

Depending on the design, an external surface 130S3 of a vertical connection member 130 may not belong to a side surface of the semiconductor package 1000a. Instead, an external surface of an encapsulant 140 may be a portion of the side surface of the semiconductor package 1000a.

FIG. 2 is a cross-sectional view illustrating a structure in which a semiconductor package 1000 includes an additional semiconductor package 200 according to example embodiments of the present inventive concept. FIG. 6B is a cross-sectional view illustrating a structure in which a semiconductor package 1000b includes additional semiconductor chips 220 according to example embodiments of the present inventive concept.

Referring to FIGS. 2 and 6B, the semiconductor packages 1000 and 1000b according to example embodiments of the present inventive concept may further include bumps 260 are in direct contact with bump connection portions 150. Each of the bumps 260 and additional bumps 160 may have a form of a ball or pillar, may contain or include a metal material (for example a solder, tin (Sn), lead (Pb), bismuth (Bi), and alloys thereof) having a melting point lower than those of a pad 152 and an additional pad 165, may be connected to and fixed to the pad 152 and the additional pad 165 using a reflow process or a thermal compression bonding (TCB) process, and may be connected to and fixed to connection targets (for example, the additional semiconductor package 200 or the additional semiconductor chips 220).

The additional semiconductor chips 220 may be implemented in substantially the same manner as a semiconductor chip 120, and thus the semiconductor chip 120 may include the additional semiconductor chips 220. The additional semiconductor chips 220 of FIG. 6B may be connected to the bumps 260 using a flip-chip bonding method.

Referring to FIG. 2, the additional semiconductor package 200 may include the additional semiconductor chips 220, and the additional semiconductor chips 220 may be electrically connected to a substrate 210 through a wire WB using a wire bonding method. The additional semiconductor chips 220 may be stacked in a third direction D3, and may be implemented as memory chips.

The substrate 210 may be electrically connected to the bumps 260, may have a structure in which at least one of interconnection layers 211, 212, and 213 and at least one insulating layer are alternately stacked, and may be implemented as a printed circuit board. The additional semiconductor package 200 may include an additional encapsulant 230 encapsulating the additional semiconductor chips 220, and the additional encapsulant 230 may be implemented in substantially the same manner as an encapsulant 140.

Depending on the design, the semiconductor package 1000b may further include a passive component 190 connected to a lower side of the semiconductor package 1000b through an additional bump 160. The passive component 190 may be configured to provide impedance to a redistribution structure 110 or the semiconductor chip 120. The passive component 190 may include a body 191 forming impedance, and external electrodes 192 provide the impedance of the body 191 to the outside of the passive component 190. For example, the passive component 190 may be a land-side capacitor (LSC).

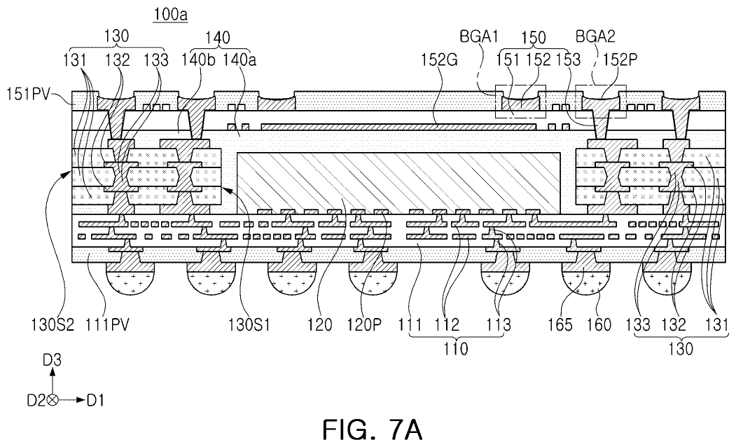

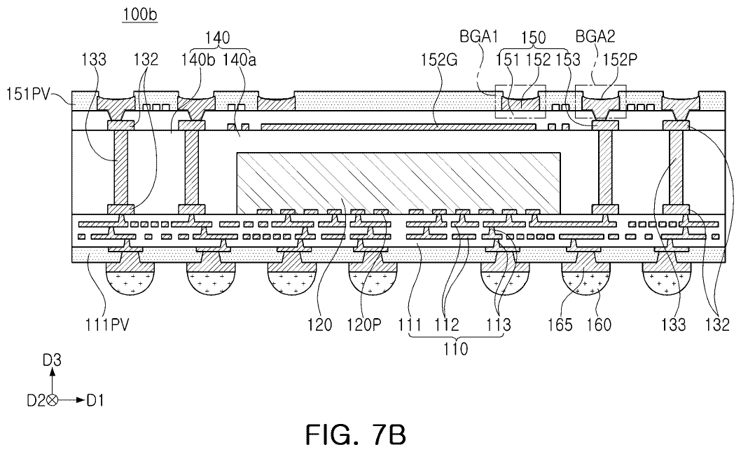

FIGS. 7A and 7B are cross-sectional views illustrating various structures of vertical connection members of semiconductor packages 100a and 100b according to example embodiments of the present inventive concept.

Referring to FIG. 7A, a vertical connection member 130 of the semiconductor package 100a according to example embodiments of the present inventive concept may have a built-up structure in a positive third direction D3 and a negative third direction D3. The vertical connection member 130 of FIG. 1 may have a built-up structure in the positive third direction D3. A direction of the build-up may correspond to a formation direction of a connection member via 133, and the formation direction of the connection member via 133 may correspond to a size relationship between an upper width and a lower width of the connection member via 133. In addition, the number of connection member insulating layers 131 and a thickness of one connection member insulating layer 131 of FIG. 7A may be different from the number of connection member insulating layers 131 and a thickness of one connection member insulating layer 131 of FIG. 1. For example, the vertical connection member 130 of FIGS. 1 and 7A may be formed using a fan-out panel level package (FOPLP) method.

Referring to FIG. 7B, a vertical connection member of the semiconductor package 100b according to example embodiments of the present inventive concept may not include a connection member insulating layer. For example, a connection member conductive layer 132 and a connection member via 133 may be formed using a wafer level package (WLP) method, and may be implemented as a conductive pillar such as a copper post (Cu post). For example, the connection member via 133 may be formed before an encapsulant 140 is formed, and may be formed by performing a plating process on a metal material (for example, copper) in through-holes of a photoresist temporarily formed before the encapsulant 140 is formed, or by performing a process of filling conductive paste in the through-holes. FIGS. 7A and 7B illustrate a fan-out package structure, but the semiconductor packages 100a and 100b may be implemented to have a fan-in structure.

According to example embodiments of the present inventive concept, a semiconductor package may efficiently improve reliability (for example, performance to prevent at least one of voids, cracks, and delamination) of a combination structure of a pad and an insulating layer.

While example embodiments have been shown and described above, it will be apparent to those skilled in the art that modifications and variations could be made without departing from the scope of the present inventive concept as defined by the appended claims.

What is claimed is:

1. A semiconductor package comprising:
a first insulating layer;
a second insulating layer on the first insulating layer, the second insulating layer having an opening;
a pad on the first insulating layer or the second insulating layer to at least partially vertically overlap the opening; and
a pad surface layer on an upper surface of the pad to at least partially vertically overlap the opening, the pad surface layer including a conductive material different from that of the pad,
wherein the upper surface of the pad is recessed to have a shape more curved than that of a lower surface of the pad.

2. The semiconductor package of claim 1, wherein the upper surface of the pad has upwardly concave shape.

3. The semiconductor package of claim 1, wherein a central region of the pad is thinner than an edge region of the pad.

4. The semiconductor package of claim 1, wherein an upper portion of a side surface of the pad is more inclined than a lower portion of the side surface of the pad relative to vertical.

5. The semiconductor package of claim 1, further comprising:
a seed layer between the first insulating layer and the pad, the seed layer including a material different from those of the pad and the pad surface layer.

6. The semiconductor package of claim 1, wherein
a central region of the pad surface layer is in contact with the pad, and
an edge of the pad surface layer is spaced apart from the pad.

7. The semiconductor package of claim 1, wherein
the pad surface layer includes first and second pad surface layers including different conductive materials, and
the first pad surface layer is between the second pad surface layer and the pad.

8. The semiconductor package of claim 7, wherein
the pad includes copper (Cu) or an alloy of copper,
the first pad surface layer includes nickel (Ni) or an alloy of nickel, and
the second pad surface layer includes gold (Au) or an alloy of gold.

9. The semiconductor package of claim 1, wherein each of the first and second insulating layers includes a build-up film.

10. The semiconductor package of claim 1, wherein the pad has a conductive via extending downwardly from the lower surface of the pad, the conductive via vertically overlapping the pad surface layer.

11. The semiconductor package of claim 1, further comprising:
a redistribution structure having a structure in which at least one redistribution layer and at least one redistribution insulating layer are alternately stacked, the redistribution structure electrically connected to the pad; and
a semiconductor chip electrically connected to the redistribution structure.

12. The semiconductor package of claim 11, further comprising:
an encapsulant encapsulating the semiconductor chip,
wherein the semiconductor chip and the encapsulant are between the redistribution structure and the first insulating layer.

13. A semiconductor package comprising:
a first insulating layer;
a second insulating layer on the first insulating layer, the second insulating layer having an opening;
a pad on the first insulating layer or the second insulating layer to at least partially vertically overlap the opening; and
a pad surface layer on an upper surface of the pad to at least partially vertically overlap the opening, the pad surface layer including a conductive material different from that of the pad,
wherein an edge of a lower surface of the pad surface layer is at a higher vertical level than a center of an upper surface of the pad surface layer.

14. The semiconductor package of claim 13, wherein the pad surface layer has an upwardly concave shape.

15. The semiconductor package of claim 13, wherein
an upper portion of a side surface of the pad is more inclined than a lower portion of the side surface of the pad relative to vertical,
a central region of the pad surface layer is in contact with the pad, and
an edge of the pad surface layer is spaced apart from the pad.

16. The semiconductor package of claim 13, further comprising:
a redistribution structure having a structure in which at least one redistribution layer and at least one redistribution insulating layer are alternately stacked, the redistribution structure electrically connected to the pad;
a semiconductor chip electrically connected to the redistribution structure; and
an encapsulant encapsulating the semiconductor chip,
wherein the semiconductor chip and the encapsulant are between the redistribution structure and the first insulating layer.

17. A method of manufacturing a semiconductor package, the method comprising:
forming a pad on a seed layer on a first insulating layer, and forming a mask layer on an edge region of the pad and the seed layer;
etching a portion of a central region of the pad;
plating the central region of the pad;
removing the mask layer; and
etching a portion of the seed layer not vertically overlapping the pad.

18. The method of claim 17, wherein the etching the portion of the central region of the pad includes etching a portion of the central region of the pad using an etching method involving a chemical reaction.

19. The method of claim 17, wherein the etching the portion of the central region of the pad includes etching a portion of the central region of the pad using a wet etching method.

20. The method of claim 17, wherein the mask layer includes dry film photoresist.
